(19) United States
(12) Patent Application Publication
(10) Pub. No.: US 2012/0126804 A1
(43) Pub. Date: May 24, 2012

(54) APPARATUS AND METHOD FOR DETECTING FAULTY CONCENTRIC NEUTRALS IN A LIVE POWER DISTRIBUTION CABLE

(75) Inventors: Richard M. White, Berkeley, CA (US); Igor Paprotny, Berkeley, CA (US); Michael Seidel, Oakland, CA (US); Kanna Krishnan, Oakland, CA (US); Eli S. Leland, Oakland, CA (US)

(73) Assignee: University of California, Berkeley, CA (US)

(21) Appl. No.: 13/113,957

(22) Filed: May 23, 2011

Related U.S. Application Data
(60) Provisional application No. 61/351,758, filed on Jun. 4, 2010.

(51) Int. Cl. G01R 33/02

(52) U.S. Cl. 324/244

(57) ABSTRACT

An apparatus for detecting a faulty concentric neutral wire in a live power distribution cable may include, in one embodiment, a housing for sliding along a surface of a power distribution cable, a magnetic sensor, and a motion device. The magnetic sensor may be coupled to the housing and configured to detect a magnetic field produced by each concentric neutral wire as the housing moves along the surface of the cable. The motion device may also be coupled to the housing, and may detect motion of the housing relative to the cable. In some embodiments, a communication device may communicate data describing the magnetic field and motion to a destination device.

### BACKGROUND

This invention relates to underground electrical power distribution systems, and particularly to underground electrical power distribution cables having concentric neutral wires surrounding the cable construction.

Underground power distribution cables are used extensively to convey electrical power to diverse locations. Typical power distribution cables are characterized by a central conductor surrounded by one or more concentric neutral wires. In some cases, the concentric neutral (“CN”) wires are helically wound around the central conductor. Such concentric neutral wires provide a phase imbalance current return path, and ensure that the outside surface of the cable insulation is at ground potential. In addition, the concentric neutral wires provide a path to ground for any fault currents that might occur such as for example when the cable is struck by lightning, or when an implement, such as a shovel, accidentally cuts into the cable.

Because concentric neutral wires are wound around the outside of power distribution cables, however, they are particularly vulnerable to corrosion, damage, or other harmful effects of the underground environment in which they reside. Indeed, the integrity of such wires may be impaired by moisture, aging, corrosive chemicals, underground mechanical stresses, or the like. Harmful mechanical stresses may include stresses imposed by pressure, freezing and thawing cycles, abrasive elements, pulling through conduit, damage by underground rodents, or the like.

The relative inaccessibility of the cable once it is placed in the ground can be problematic for monitoring and maintaining the cable and its concentric neutrals. Regulations demand that cables with faulty concentric neutrals be replaced, necessitating regular inspection of the power cable. Traditional methods, however, require that portions of the cable be taken out of service for inspection and maintenance. Accordingly, inspection and testing of underground cables and concentric neutrals often occurs less frequently and with higher costs than desired.

In view of the foregoing, what are needed are apparatus and methods to measure currents flowing in concentric neutral wires without interrupting power service. Further what are needed are apparatus and methods to facilitate quick identification and replacement of cables having faulty concentric-neutral wires. Such apparatus and methods are disclosed and claimed herein.

### BRIEF DESCRIPTION OF THE DRAWINGS

In order that the advantages of the invention will be readily understood, a more particular description of the invention briefly described above will be rendered by reference to specific examples illustrated in the appended drawings. Understanding that these drawings depict only typical examples of the invention and are not therefore to be considered limiting of its scope, the invention will be described and explained with additional specificity and detail through the use of the accompanying drawings, in which:

FIG. 1 is a perspective view of a jacketed underground power distribution cable;

FIG. 2a is a side view of a sensing device for detecting a faulty concentric neutral wire in a live power distribution cable in accordance with certain embodiments of the invention;

FIG. 2b is an end view of the sensing device of FIG. 2a;

FIG. 3 is a side view of a sensing device sliding axially along a surface of a power distribution cable in accordance with embodiments of the present invention;

FIG. 4a is a side view of an alternative embodiment of a sensing device for detecting a faulty concentric neutral wire in a live power distribution cable in accordance with certain embodiments of the invention;

FIG. 4b is an end view of the sensing device of FIG. 4a;

FIG. 5 is an end view of a sensing device sliding circumferentially along a surface of a power distribution cable in accordance with embodiments of the invention;

FIG. 6 a schematic view of a system in accordance with certain embodiments of the invention, where a sensing device is affixed to a cable and transmitting magnetic field data to a computer or other data collecting device;

FIG. 7a is an exemplary plot of measured output of a sensing device in accordance with embodiments of the present invention with all concentric neutral wires intact;

FIG. 7b is an exemplary plot of measured output of a sensing device in accordance with embodiments of the invention where one concentric neutral wire is corroded, cut or not functioning properly;

FIG. 8a is an exemplary fourier transform of the measured output of a sensing device in accordance with embodiments of the present invention with all concentric neutral wires intact; and

FIG. 8b is an exemplary fourier transform of the measured output of a sensing device in accordance with embodiments of the present invention with one concentric neutral wire not functioning properly.

### DETAILED DESCRIPTION

The invention has been developed in response to the present state of the art, and in particular, in response to the problems and needs in the art that have not yet been fully solved by currently available methods and apparatus for detecting faulty concentric neutral wires in live power distribution cables. Accordingly, the invention has been developed to provide a novel apparatus and method for detecting a faulty concentric neutral wire to facilitate condition-based replacement of a power distribution cable. The features and advantages of the invention will become more apparent from the following description and appended claims and their equivalents, and also any subsequent claims or amendments presented, or may be learned by practice of the invention as set forth hereinafter.

In one embodiment, an apparatus for detecting a faulty concentric neutral wire in a live power distribution cable may include a housing for sliding along a surface of a power distribution cable, a magnetic sensor, and a motion device. The magnetic sensor may be coupled to the housing and configured to detect a magnetic field produced by each concentric neutral wire as the housing moves along the surface of the cable. The motion device may also be coupled to the housing, and may detect motion of the housing relative to the cable.

In another embodiment, a method for detecting a faulty concentric neutral wire in a live power distribution cable may include locating a live power distribution cable having multiple concentric neutral wires associated therewith. A magnetic sensor may slide along a surface of the cable to sense a magnetic field produced by each of the concentric neutral wires. Motion of the magnetic sensor relative to the live power distribution cable may be detected, and data describing the magnetic field and motion may be transmitted to a destination device.

In yet another embodiment, a system for detecting a faulty concentric neutral wire in a live power distribution cable may include a housing, one or more magnetic sensors, a communication device, and a destination device. The housing may be coupled to a surface of a power distribution cable. The magnetic sensors may be coupled to the housing to detect a magnetic field produced by each concentric neutral wire of the power distribution cable. The communication device may communicate data describing the magnetic field to the destination device. The destination device may then receive and analyze the data to identify abnormalities in the magnetic field characteristic of a faulty concentric neutral wire.

It will be readily understood that the components of the present invention, as generally described and illustrated in the Figures herein, could be arranged and designed in a wide variety of different configurations. Thus, the following more detailed description of the embodiments of apparatus and methods in accordance with the present invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

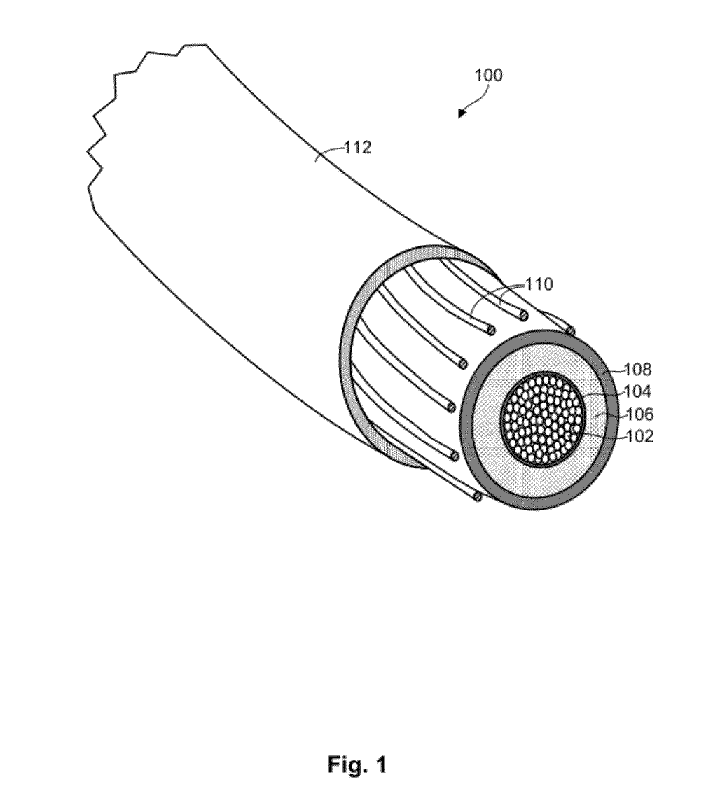

With reference now to FIG. 1, an underground power distribution cable 100 is typically an elongate, cylindrically-symmetric structure having a center conductor 102 designed to carry large electrical currents. The center conductor 102 may be a metallic conductor, such as solid or stranded copper or aluminum, or any other suitable conductor known to those in the art. The center conductor 102 may be surrounded by one or more semiconductive shields 104 and 108 and a dielectric insulating layer 106. In some embodiments, the dielectric insulating layer 106 may be sandwiched between inner and outer semiconductive shields 104 and 108, such that the semiconductive shields 104 and 108 may smooth out electrical fields through the dielectric insulating layer 106. The semiconductive shields 104, 108 may include, for example, a thin layer of a semi-conductive polymeric compound, such as a semi-conductive cross-linked polyethylene (“XLPE”) compound. The dielectric insulating layer 106 may include, for example, polyethylene, XLPE, ethylene-propylene-rubber (“EPR”), or the like.

Multiple concentric neutral wires 110 may be substantially evenly spaced to surround and directly contact the outer semiconductive shield 108. In some embodiments, the concentric neutral wires 110 may include copper or aluminum wires helically wound around the outer semiconductive shield 108. In operation, the concentric neutral wires 110 may be at ground potential to protect against large current that might flow if the cable 100 is struck by lightening or accidentally hit or cut with an implement, such as a shovel. In certain embodiments, a polymeric jacket 112 may be extruded over the concentric neutral wires 110 to further insulate and protect the cable 100. The jacket 112 may be made of, for example, linear low density polyethylene, medium density polyethylene, or semi-conductive polyethylene.

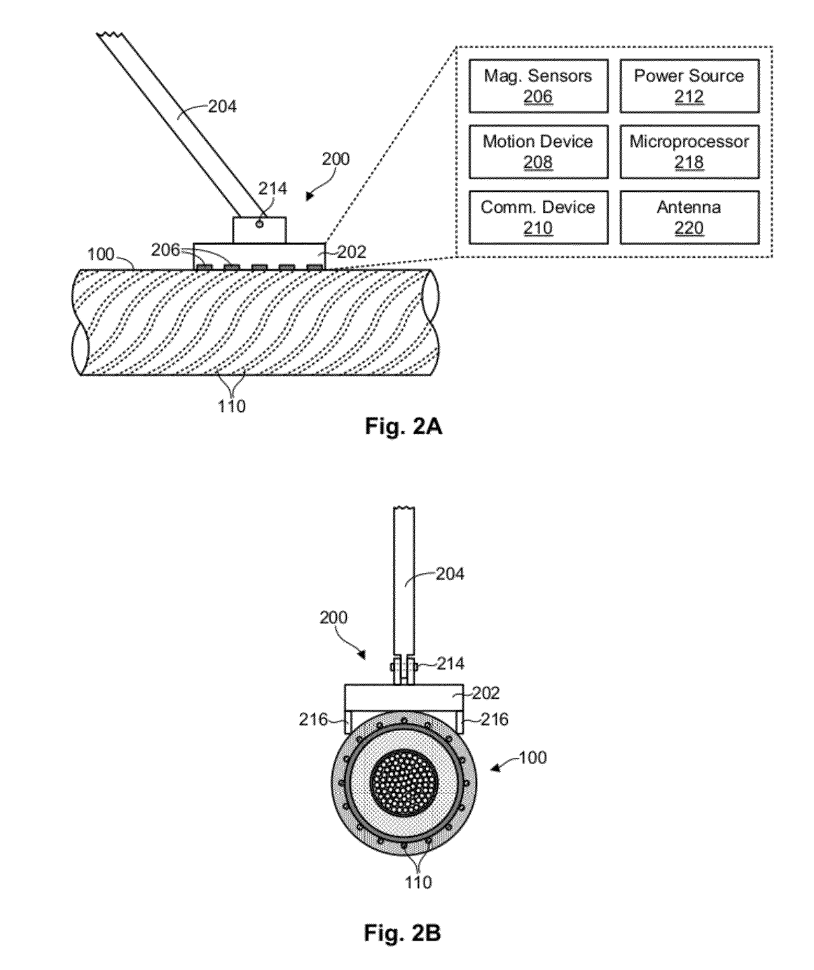

Referring now to FIG. 2A, a sensing device 200 for detecting a faulty concentric neutral wire 110 in accordance with embodiments of the invention may include a housing 202 for sliding along a surface of a power distribution cable 100. As shown, the housing 202 may attach to a hot stick 204 or other device known to those in the art for safely maneuvering a tool in contact with an energized high-voltage electric power line or cable 100. In certain embodiments, the housing 202 may pivot 214 with respect to the hot stick 204 to facilitate uninterrupted contact with the power distribution cable 100 during operation.

In some embodiments, the housing 202 may include one or more substantially transparent regions to facilitate transmission and receipt of optical signals from devices or components contained within the housing 202, as discussed in more detail below. Further, the housing 202 may include one or more regions that are substantially transparent to radio frequency or other communication signals known to those in the art. In certain embodiments, the housing 202 may be substantially hermetically sealed to protect internal components from moisture and other environmental damage.

Internal components may include, for example, a motion device 208 and a magnetic sensor 206. The motion device 208 may detect motion of the housing 202 relative to the power distribution cable 100. For example, in some embodiments the motion device 208 may include an optical or laser source and an optical detector, such that the detector may detect the laser light reflected from the surface of the cable 100 to track linear motion of the device 208 along the surface of the cable 100. Since the motion device 208 may be contained within the housing 202, the motion detected by the motion device 208 may be attributed to the motion of the housing 202 relative to the cable 100. This motion may be communicated from the motion device 208 to a destination device (not shown) to facilitate processing and identification of a faulty concentric neutral wire 110.

One or more magnetic sensors 206 may also be contained within the housing 202 to sense magnetic fields produced by each of the concentric neutral wires 110 as the housing 202 slides along a surface of the cable 100. As shown in FIGS. 2A and 2B, one embodiment of the invention may include multiple magnetic sensors 206 contained within the housing 202. Multiple concentric neutral wires 110 may be helically wound around the power distribution cable 100, such that each of the magnetic sensors 206 corresponds to a concentric neutral wire 110. The housing 202 may slide axially along a surface of the cable 100 to ensure detection of the magnetic fields produced by each of the concentric neutral wires 110.

The magnetic sensors 206 may also detect ambient magnetic fields produced by the center conductor 102 and semiconductors 104, 108. Since the magnitude of these ambient magnetic fields is typically the same along a length of the power distribution cable 100, however, such measurements generally do not affect concentric neutral wire 110 testing. In fact, in some embodiments, as discussed in more detail below, an algorithm (such as a fourier transform) may be applied during later processing to highlight only the magnetic fields produced by the concentric neutral wires 110.

In certain embodiments, the magnetic sensor 206 may be a meso-scale or microfabricated piezoelectromechanical current sensor, such that the magnetic field produced by the concentric neutral wire 110 causes a response of the magnetic sensor 206 that is proportional to the strength of the magnetic field. In other embodiments, the magnetic sensor 206 may employ magnetoresistive effects to measure magnetic field strength along one or more orthogonal axes. Such magnetoresistive effects may include, for example, anisotropic magnetoresistance (“AMR”), giant magnetoresistance (“GMR”), and any other magnetoresistive effects known to those in the art. In other embodiments, the magnetic sensor may employ non-piezoelectric and non-magnetoresistive effects, such as the Hall effect.

In some embodiments, the housing 202 may further house a communication device 210, such as a radio chip, to communicate motion and/or magnetic field data from the sensing device 200 to a destination device (not shown). The communication device 210 may communicate with a destination device over a network such as a wi-fi network, a cellular network, a satellite network, a power-line network or any other suitable network known to those in the art. In certain embodiments, the communication device 210 may include a network interface to communicate with such a network. The network interface may enable a wired or wireless connection between the communication device 210 and the network. If wireless communication is used, the communication device 210 may transmit signals over an antenna 220.

The housing 202 may further include a power source 212 to provide power to any or all of the motion device 208, the magnetic sensor 206, and the communication device 210. In certain embodiments the power source 212 may include a battery, or may scavenge energy emitted by the power distribution cable 100. For example, magnetic fields emitted by the power distribution cable 100 may be converted to electrical energy with a transformer, such as one or more conductive loops, or the like. A microprocessor 218 may be provided to control operation of the sensing device 200.

Referring now to FIG. 2B, in some embodiments, the sensing device 200 may include one or more guides 216 coupled to or integrated with the housing 202. The guides 216 may extend from outer edges of the housing 202 to provide additional points of contact between the housing 202 and the power distribution cable 100. In this manner, the guides 216 may facilitate continuous contact and proper alignment between the housing 202 and the power distribution cable 100 as it slides along a surface thereof

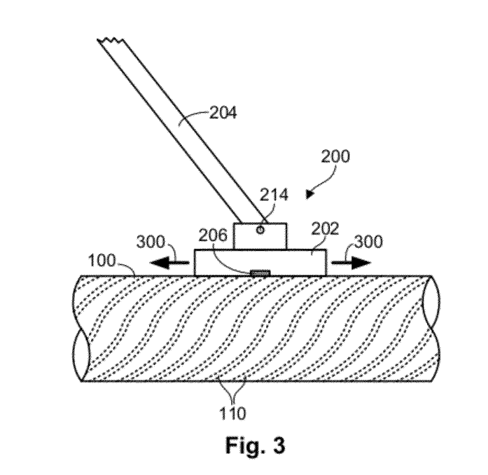

Referring now to FIG. 3, certain embodiments of the invention may include a single magnetic sensor 206 designed to measure magnetic fields produced by each concentric neutral wire 110 in succession. Adjacent concentric neutral wires 110 surrounding the power distribution cable 100 may be substantially evenly spaced with respect to each other. Where the concentric neutral wires 110 are helically wound around the power distribution cable 100, sliding the housing 202 in an axial direction 300 along a surface of the power distribution cable 100 may permit the magnetic sensor 206 to substantially align with each of the concentric neutral wires 110 at least once. In this manner, magnetic fields produced by each of the concentric neutral wires 110 may be measured and compared to identify one or more faulty concentric neutral wires 110.

The distance that the housing 202 must travel in an axial direction 300 to enable the magnetic sensor 206 to encounter each of the concentric neutral wires 110 at least once may be easily ascertained based on the diameter of the wires 110 and the distance between adjacent wires 110. Generally, the distance required for a single magnetic sensor 206 to sense each concentric neutral wire 110 may be about a foot and a half. As a result, embodiments of the invention may enable a user to quickly and easily test the power distribution cable 100 to determine the functionality of concentric neutral wires. Advantageously, this testing may occur 110 without disrupting power service. In addition, embodiments of the invention may require temporary access to only one end of the power distribution cable 100, such as that contained within a cable vault, to identify a faulty concentric neutral wire 110. As a result, the condition of the power distribution cable 100 may be easily assessed while avoiding the usual problem of power distribution cable 100 inaccessibility.

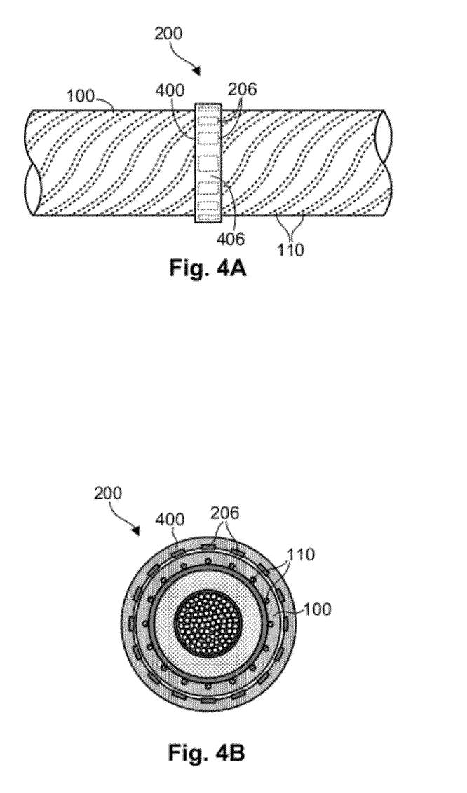

Referring now to FIGS. 4a and 4b, an alternative embodiment of a sensing device 200 for detecting a faulty concentric neutral wire 110 in a live power distribution cable 100 in accordance with the present invention may include a housing or collar 400 having one or more magnetic sensors 206 integrated therein or coupled thereto. The collar 400 may have a length sufficient to substantially circumscribe an outer circumference of a power distribution cable 100. In some embodiments, the circumference of the collar 400 (when ends of the collar 400 are joined) may be adjustable to accommodate a variety of power distribution cable 100 circumferences. In other embodiments, the circumference of the collar 400 may be substantially fixed.

One or more magnetic sensors 206 may be integrated into or coupled to the collar 400 along its length to substantially align with one or more concentric neutral wires 110 in a power distribution cable 100. Particularly, as shown in FIG. 4a, one embodiment includes multiple magnetic sensors 206 integrated into the collar 400 and spaced a fixed distance 406 from one another along the length of the collar 400. The dimensions and angles of the magnetic sensors 206, as well as the distance 406 between such sensors 206, may be selected such that one magnetic sensor 200 substantially corresponds to one concentric neutral wire 110 when the collar 400 is attached circumferentially around a power distribution cable 100. In one embodiment, the magnetic sensors 206 are arranged at a predetermined, finite angle with respect to the axis of the power distribution cable 100 such that the sensing device 200 may be universally applied to sense magnetic fields produced by concentric neutral wires 110 of a power distribution cable 100 having any diameter.

In certain embodiments, the collar 400 may be substantially fixed with respect to the power distribution cable 100, such that magnetic fields produced by each of the concentric neutral wires 110 may be monitored over an extended period of time. A microprocessor (not shown) may be provided to control operation of the magnetic sensors 206 and sensing device 200.

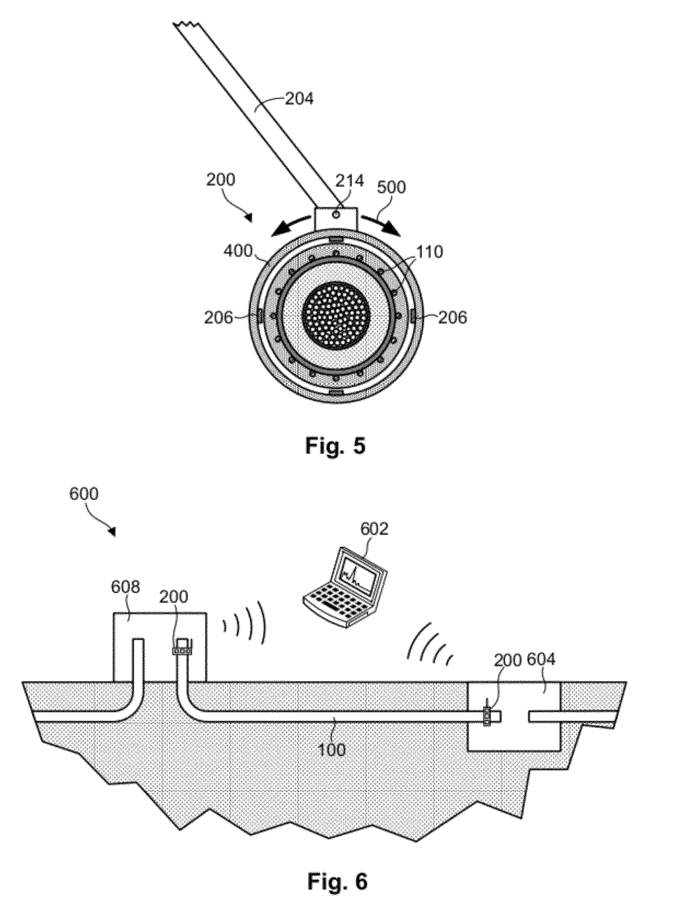

In other embodiments, the collar 400 may be removably attached to the power distribution cable 100 to obtain magnetic field measurements from each of the concentric neutral wires 110 at specific, discrete times, or as needed. For example, as shown in FIG. 5, one embodiment may include a collar 400 having a few or a single magnetic sensor 206 that may be rotated around an outer circumference of a power distribution cable 100. The magnetic sensor 206 may thus sense magnetic fields produced by each concentric neutral wire 110 in succession, as discussed in more detail below. In another embodiment, the collar 400 may include more than one magnetic sensor 206 to successively sense magnetic fields produced by concentric neutral wires 110 as the collar moves circumferentially around the power distribution cable 100.

In such embodiments, a motion device (not shown) coupled to the housing or collar 400 may detect motion of the collar 400 relative to the power distribution cable 100. The motion device may include, for example, an optical motion detector, a mechanical motion device, a resistive potentiometer, or other suitable position tracking or motion device known to those in the art.

A communication device (not shown) may also be coupled to the housing or collar 400 to communicate data describing the magnetic fields produced by the concentric neutral wires 110 and/or motion of the collar 400 relative to the power distribution cable 100. The communication device may enable communication between the sensing device 200 and a destination device over a network. The network may include, for example, a wi-fi network, a cellular network, a satellite network, a power-line network or any other suitable network known to those in the art.

A power source (not shown) may be coupled to the housing or collar 400 to provide energy for the magnetic sensors 206, motion device, and/or communication device. The power source may include a battery, a device to scavenge energy from the magnetic or electric fields produced by the cable 100, or any other suitable power source known to those in the art.

Referring now to FIG. 5, adjacent concentric neutral wires 110 may surround an outer surface of a power distribution cable 100, or may lie directly beneath a jacket 112 extruded over the cable 100. In some embodiments, the sensing device 200 may include a housing or collar 400 substantially encircling an outer circumference of the power distribution cable 100. In one embodiment, a single magnetic sensor 206 disposed in the collar 400 may sense magnetic fields produced by each of the concentric neutral wires 110.

Specifically, as shown in FIG. 5, the housing or collar 400 may be rotated in a circumferential direction 500 around the power distribution cable 100 to enable the magnetic sensor 206 to sense the magnetic fields produced by each of the concentric neutral wires 110. In some embodiments, a hot stick 204 or other suitable device may be attached to the collar 400 via a pivot point 214 to facilitate circumferential rotation.

In embodiments having multiple magnetic sensors 206, where each magnetic sensor 206 corresponds to a single concentric neutral wire 110, rotating the collar 400 around the power distribution cable 100 may facilitate alignment between each magnetic sensor 206 and a corresponding concentric neutral wire 110, thereby promoting the sensing capability of each sensor 206. In other embodiments having fewer magnetic sensors 206 than concentric neutral wires 110, rotating the collar 400 around the circumference of the power distribution cable 100 may ensure that the magnetic fields produced by each of the concentric neutral wires 110 are sensed at least once.

Referring now to FIG. 6, a system 600 for detecting a faulty concentric neutral wire 110 in a live power distribution cable 100 may include a sensing device 200 having a housing 202 coupled to a surface of the power distribution cable 100, and one or more magnetic sensors 206 coupled to the housing 202. The housing 202 may be fixedly or removably attached to the power distribution cable 100. The one or more magnetic sensors 206 may detect a magnetic field produced by each concentric neutral wire 110 of the power distribution cable 100.

Data describing the magnetic field sensed may be communicated from the sensing device 200 to a remote destination device 602 by way of a communication device 210 associated with the sensing device 200. In some embodiments, the communication device 210 may be contained within the housing 202, or attached to the housing 202. The communication device 210 may include a radio chip, cable, antenna or the like to communicate radio frequency, wi-fi, power-line or other types of signals to the destination device 602. The destination device 602 may receive and analyze the data to identify abnormalities in the magnetic fields that may indicate a faulty concentric neutral wire 110.

In some embodiments, the sensing device 200 may further include a motion device (not shown) to detect motion of the device 200 relative to the power distribution cable 100. As discussed in more detail above with reference to FIGS. 2 and 4 above, the motion device may facilitate correlating an abnormal magnetic field reading with a particular concentric neutral wire 110, and in some cases, may facilitate proper alignment between a magnetic sensor 206 and a concentric neutral wire 110 during testing.

As shown in FIG. 6, some embodiments of a system 600 for detecting a faulty concentric neutral wire 110 may include an underground power distribution cable 100 having one end accessible from an above-ground switch box 608 or underground cable vault 604. The sensing device 200 may be fixedly or removably attached to the end of the power distribution cable 100 accessible in the switch box 608 or cable vault 604, such that a user may quickly and easily access the device 200 and/or cable 100 to perform a maintenance check.

In one embodiment, the sensing device 200 is substantially permanently attached to the underground power distribution cable 100 to monitor the integrity of the concentric neutral wires 110 over time. The communication device 210 may automatically and/or periodically relay the sensed magnetic fields to a destination device 602 for analysis. In some embodiments, the destination device 602 may similarly relay signals to the sensing device 200 to prompt a reading of the magnetic fields produced by the concentric neutral wires 110.

The destination device 602 may include, for example, a remotely located computer or processing system, a laptop computer, a cell phone, a smart phone, or the like. In some embodiments, the destination device 602 may store measured data from successive sensing operations to monitor progressive degradation of concentric neutral wires 110.

Monitoring concentric neutral wires 110 in this manner may facilitate regular testing and frequent analysis of test results, thereby enabling prompt identification and replacement of a power distribution cable 100 having one or more faulty concentric neutral wires 110. Advantageously, in some embodiments, such monitoring and analysis may occur without requiring repeated human access to and contact with an underground power distribution cable 100 for testing purposes.

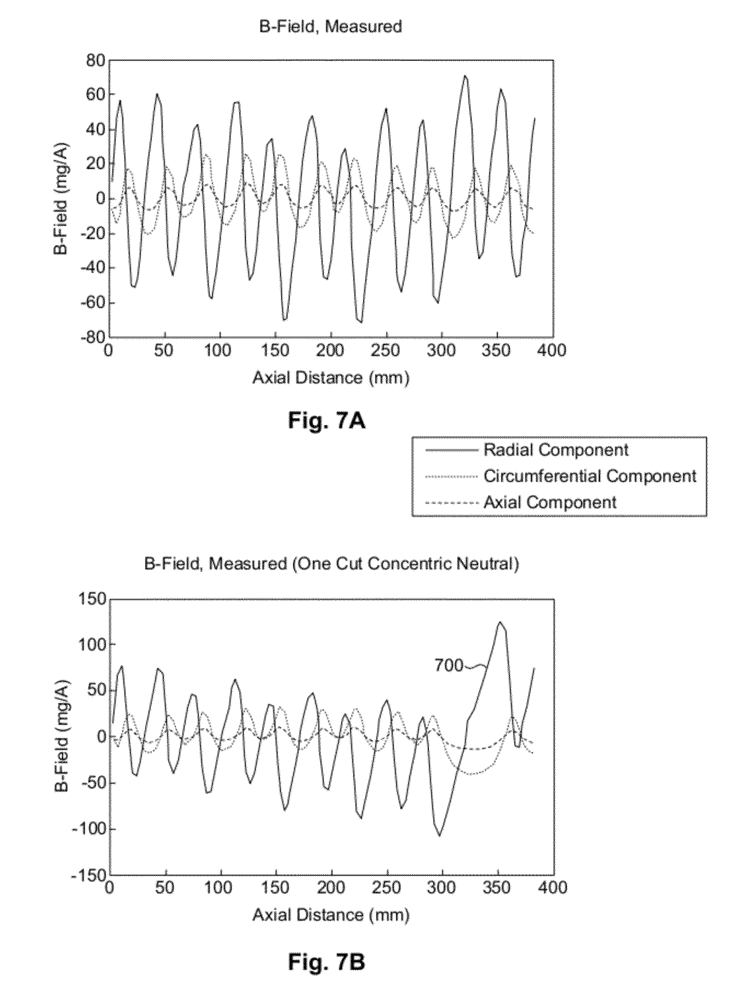

FIGS. 7a and 7b illustrate examples of data that may be obtained from the sensing device 200 and transmitted to a destination device 602 for analysis. FIG. 7a depicts exemplary data from a power distribution cable 100 having all concentric neutral wires 110 in proper working order, while FIG. 7B depicts exemplary data from a power distribution cable 100 where one concentric neutral wire 110 has been severed or corroded.

As shown, the magnetic fields produced by the concentric neutral wires 110 and measured by the sensing device 616 may include a radial component, a circumferential component, and an axial component owing to the helical configuration of the concentric neutral wires 110 around the power distribution cable 100. The magnitude of each of these components may be measured and analyzed with respect to an axial distance the sensing device 200 has traveled along a surface of the power distribution cable 100. Since properly functioning concentric neutral wires 110 are expected to demonstrate similar measurements for similar components, a non-functioning or deteriorating concentric neutral wire 110 may be easily identified by comparison.

For example, as shown in FIG. 7B, an irregular peak 700 in the radial component is evidenced in the data around an axial distance of 350 mm. As this is an unexpected departure from the previous, relatively periodic pattern of radial component peaks and valleys, one skilled in the art would recognize this as an indication of improper functioning of a concentric neutral wire 110 located at an axial distance of about 350 mm from the initial point of testing, such as at 0.0 mm.

In some embodiments, a human operator may perform such a comparison to identify a faulty concentric neutral wire 110. In other embodiments, a comparative analysis may be performed automatically or semi-automatically by a processor or destination device 602, as discussed in more detail below.

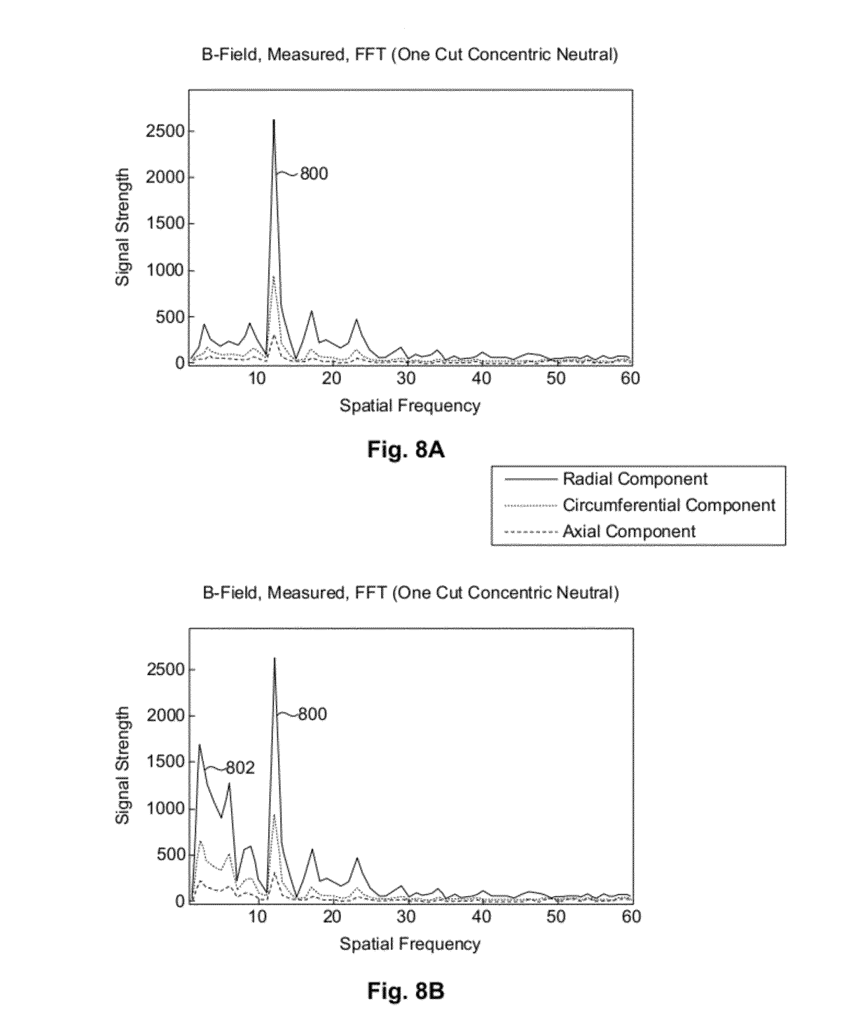

Referring now to FIGS. 8a and 8b, in certain embodiments, magnetic fields produced by the concentric neutral wires 110 may be measured by the sensing device 200 and transmitted to a destination device 602 for further processing. This processing may facilitate a user's ability to recognize an abnormal magnetic field reading, and thereby identify a power distribution cable 100 having a faulty concentric neutral wire 110.

For example, in one embodiment, the destination device 602 or other processor may apply a fourier transform or other algorithm to the data received from the sensing device 200. FIG. 8a illustrates a plot of signal strength and spatial frequency after application of a fourier transform to magnetic field data received from the sensing device 200. As shown, the resulting data approximates a single spike 800 focused around a spatial frequency of about twelve. While the spatial frequency around which the data spike 800 is focused may vary, the formation of a single spike 800 on a plot of signal strength and spatial frequency indicates that the power distribution cable 100 tested has all concentric neutral wires 110 intact. Such processing and mapping may thus enable even a novice user to quickly and accurately identify a power distribution cable 100 having all concentric neutral wires 110 in proper working order.

FIG. 8b, on the other hand, depicts an exemplary plot of signal strength and spatial frequency where a defined spike 800 in the data is preceded by a smaller, asymmetric peak 802. This asymmetric peak 802 is clearly distinct from the expected single spike 800 shape. Because of this obvious visual disparity, even an amateur user would likely be alerted to an abnormal reading from the sensing device 200.

Indeed, as shown in FIG. 8b, the unusual dual peak 802 preceding the expected spike 800 indicates that the data was obtained from a power distribution cable 100 where one of the concentric neutral wires 110 was not functioning properly. One skilled in the art will recognize, however, that the asymmetric peak 802 illustrated in FIG. 8b is just one of various ways in which an abnormal reading from the sensing device 200 may be manifest, and that any deviation from an expected result may indicate that a concentric neutral wire 110 is not functioning properly. Although it may not be obvious from the magnetic field data, an abnormal magnetic field measurement may be due to a concentric neutral wire 110 having been cut, corroded, or otherwise impaired or functionally compromised. In any case, this abnormal or irregular result may facilitate quick and accurate identification and replacement of a power distribution cable 100 having a faulty concentric neutral wire 110.

The invention may be embodied in other specific forms without departing from its spirit or essential characteristics. The described examples are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. An apparatus for detecting a faulty concentric neutral wire in a live power distribution cable, the apparatus comprising:
a housing for sliding along a surface of a power distribution cable, the power distribution cable comprising a center conductor and a plurality of concentric neutral wires surrounding the center conductor;
a magnetic sensor coupled to the housing to detect a magnetic field produced by each of the plurality of concentric neutral wires as the housing moves along the surface; and
a motion device coupled to the housing to detect motion of the housing relative to the power distribution cable.

2. The apparatus of claim 1, further comprising a communication device to communicate data describing the magnetic field and motion to a destination device.

3. The apparatus of claim 2, wherein the communication device communicates wirelessly.

4. The apparatus of claim 2, wherein the communication device communicates over a wire.

5. The apparatus of claim 1, wherein the magnetic sensor comprises a piezoelectromechanical current sensor.

6. The apparatus of claim 1, wherein the magnetic sensor further detects a magnetic field produced by at least one of a center conductor and a semiconductor.

7. The apparatus of claim 1, wherein the motion device comprises one of an optical motion sensor, a resistive potentiometer, and a mechanical motion sensor.

8. The apparatus of claim 1, wherein the housing slides axially along the surface of the power distribution cable.

9. The apparatus of claim 1, wherein the housing slides circumferentially along the surface of the power distribution cable.

10. The apparatus of claim 1, wherein the housing comprises a substantially hermetically sealed package having an optically transparent region and a radio frequency-transparent region.

11. A method for detecting a faulty concentric neutral wire in a live power distribution cable, the method comprising:
locating a live power distribution cable having a plurality of concentric neutral wires associated therewith;
sliding a magnetic sensor along a surface of the live power distribution cable to sense a magnetic field produced by each of the plurality of concentric neutral wires;
detecting motion of the magnetic sensor relative to the live power distribution cable; and
transmitting data describing the magnetic field and motion to a destination device.

12. The method of claim 11, wherein the data describing the magnetic field and motion is transmitted wirelessly.

13. The method of claim 11, wherein the data describing the magnetic field and motion is transmitted over a wire.

14. The method of claim 11, wherein the motion of the magnetic sensor is detected with an optical motion sensor.

15. The method of claim 14, wherein the magnetic sensor and the optical motion sensor are contained within a housing.

16. The method of claim 11, further comprising applying a fourier transform to the data to identify a faulty concentric neutral wire.

17. A system for detecting a faulty concentric neutral wire in a live power distribution cable, the system comprising:
a housing coupled to a surface of a power distribution cable;
at least one magnetic sensor coupled to the housing to detect a magnetic field produced by each of a plurality of concentric neutral wires of the power distribution cable;
a communication device to communicate data describing the magnetic field to an external source; and
a destination device to receive and analyze the data to identify abnormalities in the magnetic field characteristic of a faulty concentric neutral wire.

18. The system of claim 17, further comprising a motion device coupled to the housing to detect motion of the housing relative to the power distribution cable.

19. The system of claim 17, wherein the housing is substantially fixedly attached to the power distribution cable.

20. The system of claim 17, wherein the destination device further applies a fourier transform to the data to identify a faulty concentric neutral wire.
